(19) United States
(12) Patent Application Publication
(10) Pub. No.: US 2026/0358370 A1
(43) Pub. Date: Nov. 12, 2026

(54) TESTING DEVICE HAVING PROBE CONFIGURATION, PROBE CARD, AND SHEET-LIKE PROBE

(71) Applicant: CHUNGHWA PRECISION TEST TECH. CO., LTD., Taoyuan City (TW)

(72) Inventors: CHENG-YEN HSU, Taoyuan City (TW); Rong-Yang Lai, Taoyuan City (TW); HAO-YEN CHENG, Taoyuan City (TW); WEI-JHIH SU, Taichung City (TW)

(21) Appl. No.: 19/567,301

(22) Filed: Mar. 16, 2026

(30) Foreign Application Priority Data
May 9, 2025 (TW) 114117443

(51) Int. Cl. G01R 1/067; G01R 1/073; G01R 31/28

(52) U.S. Cl. CPC G01R 1/06722; G01R 1/06733; G01R 1/07378; G01R 31/2887

(57) ABSTRACT

A testing device having a probe configuration, a probe card, and a sheet-like probe. The sheet-like probe includes a fixing segment, a testing segment, a spring segment that connects the fixing segment and the testing segment, and two clamping arms that are respectively disposed at two opposite sides of the spring segment. Each of the two clamping arms has a connection end portion connected to the testing segment and a free end portion that is arranged adjacent to the fixing segment. When the sheet-like probe abuts against a device under test through the testing segment and the spring segment is pressed, the free end portions of the two clamping arms move toward and clamp the fixing segment, such that the two clamping arms, the fixing segment, and the testing segment jointly define a lateral signal transmission path.

### CROSS-REFERENCE TO RELATED PATENT APPLICATION

This application claims the benefit of priority to Taiwan Patent Application No. 114117443, filed on May 9, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an electronic testing device, and more particularly to a testing device having a probe configuration, a probe card, and a sheet-like probe.

### BACKGROUND OF THE DISCLOSURE

Although spring probes of a conventional probe card device can be used to effectively absorb force when the conventional probe card device is abutted against a device under test (DUT), a transmission speed in the conventional spring probe would be reduced due to the signal transmission path established by the conventional spring probe. Accordingly, the configuration of the conventional spring probe is gradually failing to keep up with the requirements of high stability and high speed for test processes in the relevant field.

### SUMMARY OF THE DISCLOSURE

In response to the above-referenced technical inadequacies, the present disclosure provides a testing device having a probe configuration, a probe card, and a sheet-like probe for effectively improving on the issues associated with conventional spring probes.

In order to solve the above-mentioned problems, one of the technical aspects adopted by the present disclosure is to provide a testing device having a probe configuration, which includes a probe card and a space transformer. The probe card includes a first guiding board module, a second guiding board module spaced apart from the first guiding board module along a first direction, and a plurality of sheet-like probes that are inserted into the first guiding board module and the second guiding board module. Each of the sheet-like probes is integrally formed as a single one-piece structure and includes a testing segment, a fixing segment, a spring segment and two clamping arms. The testing segment at least partially protrudes from the first guiding board module and is configured to detachably abut against a device under test (DUT). The fixing segment at least partially protrudes from the second guiding board module. The fixing segment has two lateral contacting surfaces and a bonding surface that is connected to the two lateral contacting surfaces. An arrangement distance between the two lateral contacting surfaces gradually increases in a direction away from the testing segment. The spring segment connects the fixing segment and the testing segment. The testing segment, the fixing segment, and the spring segment jointly define an initial signal transmission path. The two clamping arms are respectively arranged at two opposite sides of the spring segment. Each of the two clamping arms has a connection end portion connected to the testing segment and a free end portion that is spaced apart from the fixing segment. Each of the two clamping arms does not protrude from the first guiding board module and protrudes from the second guiding board module through the free end portion. The two lateral contacting surfaces are respectively located in two extension paths defined by extending the free end portions of the two clamping arms along the first direction, and each of the two lateral contacting surfaces is spaced apart from a corresponding one of the free end portions along the first direction by an interval. The space transformer includes a plurality of metal pads. The bonding surfaces of the fixing segments of the sheet-like probes are respectively fixed to the metal pads of the space transformer. When any one of the sheet-like probes of the probe card abuts against the DUT through the testing segment thereof and the spring segment is pressed to be shortened by a length that is greater than the interval, the free end portions of the two clamping arms move toward and abut against the two lateral contacting surfaces, respectively, and the two clamping arms swing outwardly relative to the spring segment and clamp the fixing segment through the two free end portions, so that the two clamping arms, the fixing segment, and the testing segment are jointly configured to form a lateral signal transmission path that is shorter than the initial signal transmission path.

In order to solve the above-mentioned problems, another one of the technical aspects adopted by the present disclosure is to provide a probe card, which includes a first guiding board module, a second guiding board module spaced apart from the first guiding board module along a first direction, and a plurality of sheet-like probes that are inserted into the first guiding board module and the second guiding board module. Each of the sheet-like probes is integrally formed as a single one-piece structure and includes a testing segment, a fixing segment, a spring segment and two clamping arms. The testing segment at least partially protrudes from the first guiding board module and is configured to detachably abut against a device under test (DUT). The fixing segment at least partially protrudes from the second guiding board module. The fixing segment has two lateral contacting surfaces and a bonding surface that is connected to the two lateral contacting surfaces. An arrangement distance between the two lateral contacting surfaces gradually increases in a direction away from the testing segment. The spring segment connects the fixing segment and the testing segment. The testing segment, the fixing segment, and the spring segment jointly define an initial signal transmission path. The two clamping arms are respectively arranged at two opposite sides of the spring segment. Each of the two clamping arms has a connection end portion connected to the testing segment and a free end portion that is spaced apart from the fixing segment. Each of the two clamping arms does not protrude from the first guiding board module and protrudes from the second guiding board module through the free end portion. The two lateral contacting surfaces are respectively located in two extension paths defined by extending the free end portions of the two clamping arms along the first direction, and each of the two lateral contacting surfaces is spaced apart from a corresponding one of the free end portions along the first direction by an interval. When any one of the sheet-like probes of the probe card abuts against the DUT through the testing segment thereof and the spring segment is pressed to be shortened by a length that is greater than the interval, the free end portions of the two clamping arms move toward and abut against the two lateral contacting surfaces, respectively, and the two clamping arms swing outwardly relative to the spring segment and clamp the fixing segment through the two free end portions, so that the two clamping arms, the fixing segment, and the testing segment are jointly configured to form a lateral signal transmission path that is shorter than the initial signal transmission path.

In order to solve the above-mentioned problems, yet another one of the technical aspects adopted by the present disclosure is to provide a sheet-like probe having a longitudinal direction parallel to a first direction. The sheet-like probe includes a testing segment, a fixing segment, a spring segment and two clamping arms. The testing segment is configured to detachably abut against a device under test (DUT). The fixing segment has two lateral contacting surfaces and a bonding surface that is connected to the two lateral contacting surfaces. An arrangement distance between the two lateral contacting surfaces gradually increases in a direction away from the testing segment. The spring segment connects the fixing segment and the testing segment. The testing segment, the fixing segment, and the spring segment jointly define an initial signal transmission path. The two clamping arms are respectively arranged at two opposite sides of the spring segment. Each of the two clamping arms has a connection end portion connected to the testing segment and a free end portion that is spaced apart from the fixing segment. The two lateral contacting surfaces are respectively located in two extension paths defined by extending the free end portions of the two clamping arms along the first direction, and each of the two lateral contacting surfaces is spaced apart from a corresponding one of the free end portions along the first direction by an interval. When the sheet-like probe abuts against the DUT through the testing segment thereof and the spring segment is pressed to be shortened by a length that is greater than the interval, the free end portions of the two clamping arms move toward and abut against the two lateral contacting surfaces, respectively, and the two clamping arms swing outwardly relative to the spring segment and clamp the fixing segment through the two free end portions, so that the two clamping arms, the fixing segment, and the testing segment are jointly configured to form a lateral signal transmission path that is shorter than the initial signal transmission path.

Therefore, in any one of the testing device, the probe card, and the sheet-like probe provided by the present disclosure, the two clamping arms of the sheet-like probe are in cooperation with the fixing segment to form the lateral signal transmission path that is shorter than the initial signal transmission path, thereby effectively increasing the signal transmission speed of the testing device.

Moreover, in any one of the sheet-like probes of the testing device provided by the present disclosure, the two clamping arms are limited to be in contact with the fixing segment that is fixed to the space transformer, and the two clamping arms are swingable to clamp the fixing segment, thereby effectively increasing the signal transmission stability.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a testing device having a probe configuration according to the present disclosure;

FIG. 2 is a schematic perspective view of a sheet-like probe according to the present disclosure;

FIG. 3 is a schematic enlarged view of part III of FIG. 1;

FIG. 4 is a schematic planar view showing the sheet-like probe in another configuration according to the present disclosure;

FIG. 5 is a schematic planar view showing the sheet-like probe in yet another configuration according to the present disclosure;

FIG. 6 is a schematic cross-sectional view showing the testing device of FIG. 1 that presses onto a device under test (DUT);

FIG. 7 is a schematic enlarged view of part VII of FIG. 6;

FIG. 8 is a schematic cross-sectional view showing the testing device of FIG. 6 that further presses onto the DUT;

FIG. 9 is a schematic enlarged view of part IX of FIG. 8; and

FIG. 10 is a schematic enlarged view showing the sheet-like probe of FIG. 3 in another configuration.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

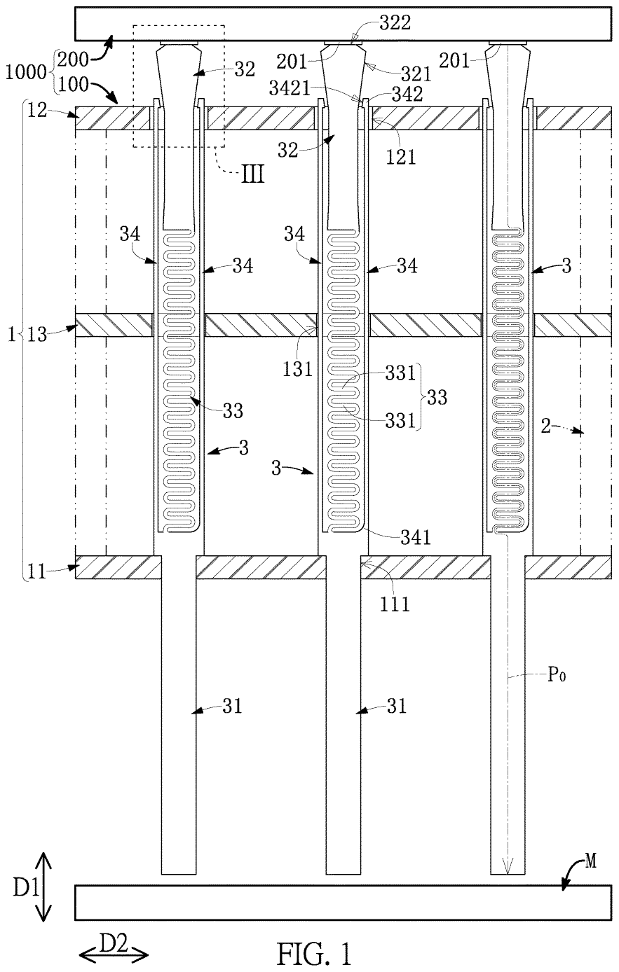

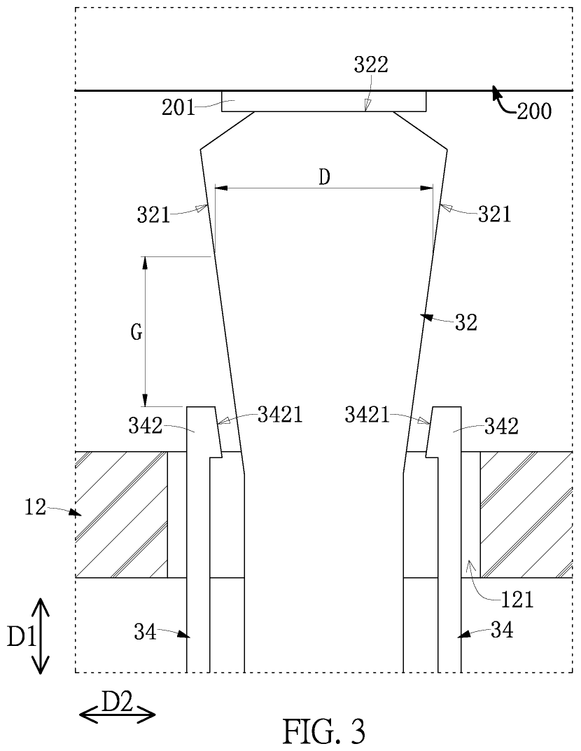

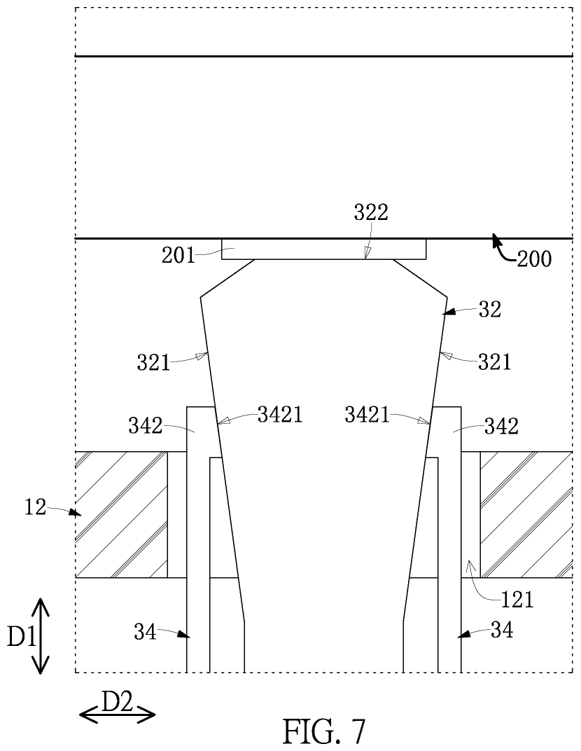

Referring to FIG. 1 to FIG. 10, an embodiment of the present disclosure is provided. As shown in FIG. 1 to FIG. 3, the present embodiment provides a testing device 1000 having a probe configuration, which includes a probe card 100 and a space transformer 200 that is fixed to one side of the probe card 100. Moreover, another side of the probe card 100 is configured to detachably abut against a device under test (DUT) M for testing the DUT M. The probe card 100 in the present embodiment is described in cooperation with the space transformer 200, but the present disclosure is not limited thereto. For example, in other embodiments of the present disclosure not shown in the drawings, the probe card 100 can be independently used (e.g., sold) or can be used in cooperation with other components.

In order to clearly describe the present embodiment, the drawings only depict a partial structure of the testing device 1000 for clearly showing the structure and connection relationship of each component of the testing device 1000, but the present disclosure is not limited by the drawings. The following description describes the structure and connection relationship of each component of the testing device 1000.

The probe card 100 in the present embodiment includes a plurality of guiding board modules 1, a spacing structure 2 sandwiched between any two of the guiding board modules 1 adjacent to each other, and a plurality of sheet-like probes 3 that are inserted into the guiding board modules 1. It should be noted that the sheet-like probe 3 in the present embodiment is described in cooperation with the guiding board modules 1 and the spacing structure 2, but the present disclosure is not limited thereto. For example, in other embodiments of the present disclosure not shown in the drawings, the sheet-like probe 3 can be independently used (e.g., sold) or can be used in cooperation with other components.

Moreover, each of the guiding board modules 1 in the present embodiment is a single guiding board and has a specific structure that can be adjusted or changed according to practical requirements, but the present disclosure is not limited thereto. For example, in other embodiments of the present disclosure not shown in the drawings, any one of the guiding board modules 1 can include two guiding boards spaced apart from each other and a ring-shaped spacing sheet that is sandwiched between the two guiding boards.

Specifically, the guiding board modules 1 in the present embodiment include a first guiding board module 11, a second guiding board module 12 spaced apart from the first guiding board module 11 along a first direction D1, and a third guiding board module 13 that is arranged between and spaced apart from the first guiding board module 11 and the second guiding board module 12 along the first direction D1. The space transformer 200 is arranged adjacent to the second guiding board module 12, but the present disclosure is not limited thereto. For example, in other embodiments of the present disclosure not shown in the drawings, the guiding board modules 1 can only include the first guiding board module 11 and the second guiding board module 12.

Moreover, the first guiding board module 11 has a plurality of first thru-holes 111 spaced apart from each other, the second guiding board module 12 has a plurality of second thru-holes 121 spaced apart from each other, and the third guiding board module 13 has a plurality of third thru-holes 131 spaced apart from each other. Each of the first thru-holes 111 substantially corresponds in position to one of the second thru-holes 121 and one of the third thru-holes 131 along the first direction D1, thereby jointly providing an insertion of one of the sheet-like probes 3.

In addition, the spacing structure 2 can include at least one ring-shaped frame and is sandwiched between peripheral portions of any two of the guiding board modules 1 adjacent to each other, but the present disclosure is not limited thereto. For example, in other embodiments of the present disclosure not shown in the drawings, the spacing structure 2 of the testing device 1000 can be omitted or can be replaced by other components.

As the sheet-like probes 3 of the testing device 1000 provided by the present embodiment are of substantially the same structure and are each integrally formed as a single one-piece structure, the following description discloses the structure and connection relationship of just one of the sheet-like probes 3 for the sake of brevity, but the present disclosure is not limited thereto. For example, in other embodiments of the present disclosure not shown in the drawings, the sheet-like probes 3 can be of different structures; or the testing device 1000 can include at least one conductive probe other than the sheet-like probe 3.

In the present embodiment, a longitudinal direction of the sheet-like probe 3 is preferably parallel to the first direction D1, but the present disclosure is not limited thereto. The sheet-like probe 3 has a testing segment 31, a fixing segment 32, a spring segment 33 that connects the fixing segment 32 and the testing segment 31, and two clamping arms 34 that are respectively arranged at two opposite sides of the spring segment 33.

The testing segment 31 at least partially protrudes from the first guiding board module 11 and is configured to detachably abut against the DUT M through an end thereof. In the present embodiment, the testing segments 31 of the sheet-like probes 3 respectively pass through the first thru-holes 111 and are positioned (or held) by the first guiding board module 11.

The fixing segment 32 at least partially protrudes from the second guiding board module 12 and is fixed to the space transformer 200 through an end thereof. In the present embodiment, the fixing segments 32 of the sheet-like probes 3 respectively pass through the second thru-holes 121.

Specifically, the fixing segment 32 has two lateral contacting surfaces 321 and a bonding surface 322 that is connected to the two lateral contacting surfaces 321. Moreover, an arrangement distance D between the two lateral contacting surfaces 321 gradually increases in a direction away from the testing segment 31. In other words, the arrangement distance D between the two lateral contacting surfaces 321 is defined along a second direction D1 perpendicular to the first direction D1. Each of the two lateral contacting surfaces 321 in the present embodiment is a plane, but in other embodiments of the present disclosure not shown in the drawings, any one of the two lateral contacting surfaces 321 can be adjusted or changed (e.g., a concave surface or a convex surface) according to practical requirements.

In addition, the space transformer 200 includes a plurality of metal pads 201, and the bonding surfaces 322 of the fixing segments 32 of the sheet-like probes 3 are respectively fixed to the metal pads 201 of the space transformer 200. The bonding surface 322 and the metal pad 201 can be fixed in a soldering manner, and the shape of the bonding surface 322 can be adjusted or changed according to practical requirements, but the present disclosure is not limited thereto.

The spring segment 33 is connected in-between the fixing segment 32 and the testing segment 31, and the spring segment 33 does not protrude from a space defined by (or arranged between) the fixing segment 32 and the testing segment 31. The spring segment 33 is substantially arranged between the first guiding board module 11 and the second guiding board module 12, and a length of the spring segment 33 is preferably greater than a length of the fixing segment 32. However, the length and structure of the spring segment 33 can be adjusted or changed according to practical requirements and are not limited by the present embodiment.

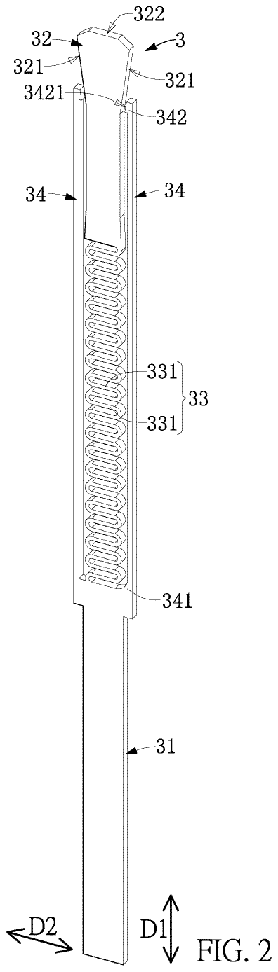

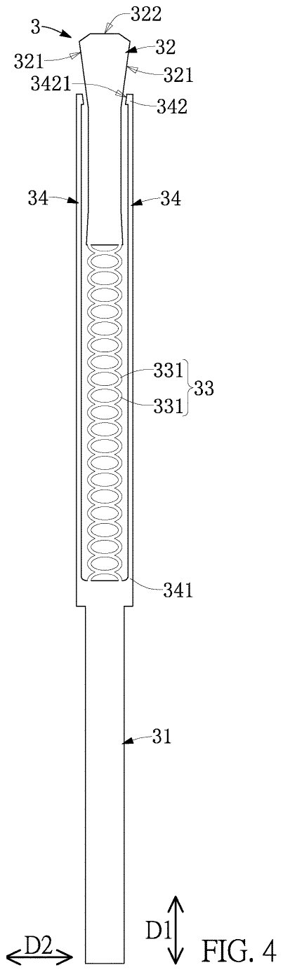

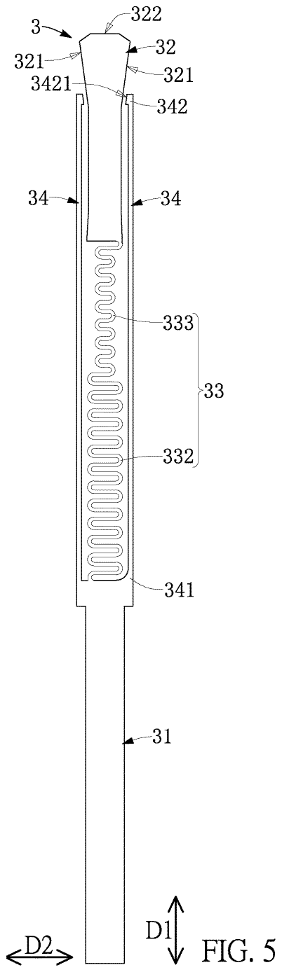

Specifically, the spring segment 33 can be elastically compressed to absorb force applied to the sheet-like probe 3. In other words, when the spring segment 33 meets the above condition, a specific structure of the spring segment 33 can be adjusted or changed according to practical requirements. For example, as shown in FIG. 2 and FIG. 4, the spring segment 33 has a plurality of elastic portions 331 that are sequentially connected to each other and that are of a same shape (e.g., a U-shape or a ring-shape). Or, as shown in FIG. 5, the spring segment 33 has a plurality of first elastic portions 332 and a plurality of second elastic portions 333, and the first elastic portions 332 and the second elastic portions 333 are sequentially connected to each other and are of different shapes. Moreover, a size of the second elastic portion 333 is smaller than that of the first elastic portion 332, such that the second elastic portion 333 is preferably arranged adjacent to the fixing segment 32.

In addition, as shown in FIG. 1 to FIG. 3, the testing segment 31, the fixing segment 32, and the spring segment 33 jointly define an initial signal transmission path P0, and since a total length of the spring segment 33 is too large, the initial signal transmission path P0 in the present embodiment is configured to not transmit signals.

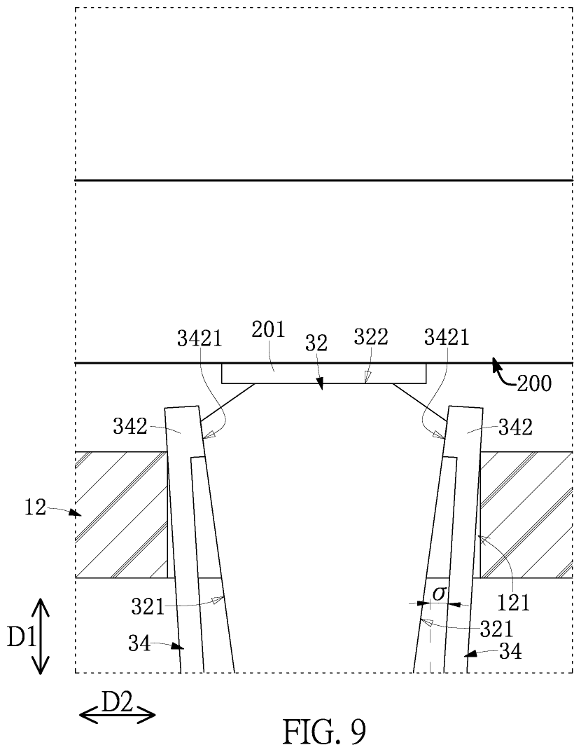

The two clamping arms 34 in the present embodiment substantially have a same length and are respectively spaced apart from the two opposite sides of the spring segment 33. Each of the two clamping arms 34 is elongated and has a connection end portion 341 connected to the testing segment 31 and a free end portion 342 that is arranged adjacent to the fixing segment 32. Each of the two clamping arms 34 is swingable relative to the spring segment 33 by taking the connection end portion 341 thereof to be a fulcrum, and each of the two clamping arms 34 is swingable outwardly relative to the spring segment 33 by a maximum swing angle σ that is less than or equal to 3 degrees (as shown in FIG. 9).

Moreover, each of the two clamping arms 34 does not protrude from the first guiding board module 11 and protrudes from the second guiding board module 12 through the free end portion 342 thereof. In other words, each of the two clamping arms 34 is inserted into a corresponding one of the third thru-holes 131 and a corresponding one of the second thru-holes 121. In the present embodiment, the connection end portions 341 of the two clamping arms 34 of each of the sheet-like probes 3 abut against an inner surface of the first guiding board module 11 that is adjacent to a corresponding one of the first thru-holes 111, thereby enabling the sheet-like probe 3 to be more firmly assembled to the first guiding board module 11.

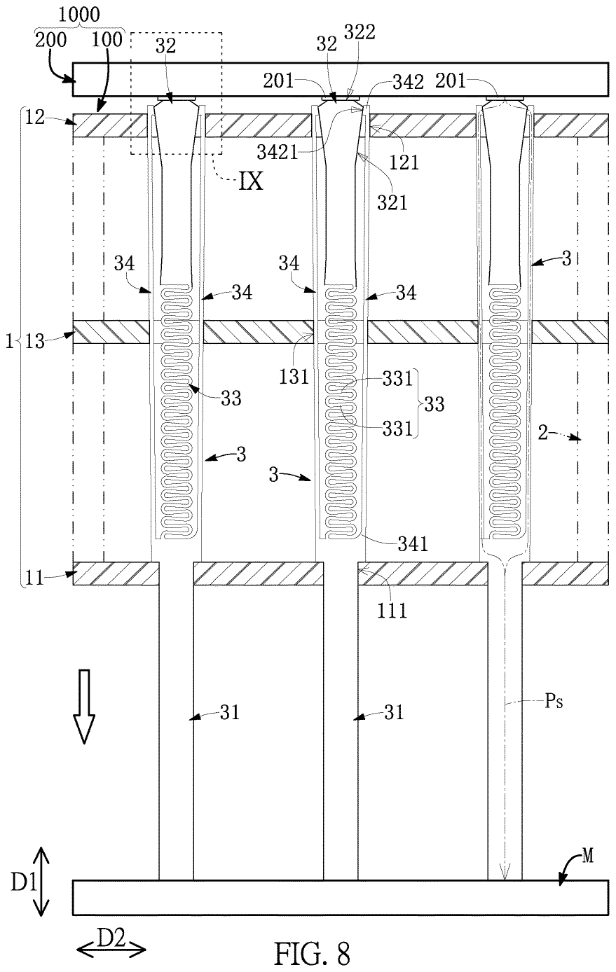

Moreover, at least one of the two clamping arms 34 of each of the sheet-like probes 3 is spaced apart from an inner wall of the corresponding third thru-hole 131 and an inner wall of the corresponding second thru-hole 121 so as to be swingable outwardly relative to the spring segment 33. In other words, as shown in FIG. 8 and FIG. 9, the maximum angle σ of each of the two clamping arms 34 can be precisely controlled through the corresponding second thru-hole 121 and/or the corresponding third thru-hole 131. In addition, when each of the two clamping arms 34 outward swings relative to the spring segment 33 at the maximum angle σ, the two clamping arms 34 can firmly clamp the fixing segment 32 by abutting against the inner wall of the corresponding second thru-hole 121 (and/or the inner wall of the corresponding third thru-hole 131).

Specifically, as shown in FIG. 1 to FIG. 3, the two lateral contacting surfaces 321 are respectively located in two extension paths defined by extending the free end portions 342 of the two clamping arms 342 along the first direction D1, and each of the two lateral contacting surfaces 321 is spaced apart from a corresponding one of the free end portions 342 along the first direction D1 by an interval G. The free end portion 342 of any one of the two clamping arms 34 has a mating surface 3421 that is parallel to the corresponding lateral contacting surface 321. In other words, as shown in FIG. 1, FIG. 8, and FIG. 9, when any one of the two clamping arms 34 swings at the maximum swing angle σ, a movable range of the mating surface 3421 is substantially located in a region defined by extending the corresponding lateral contacting surface 321 along the first direction D1.

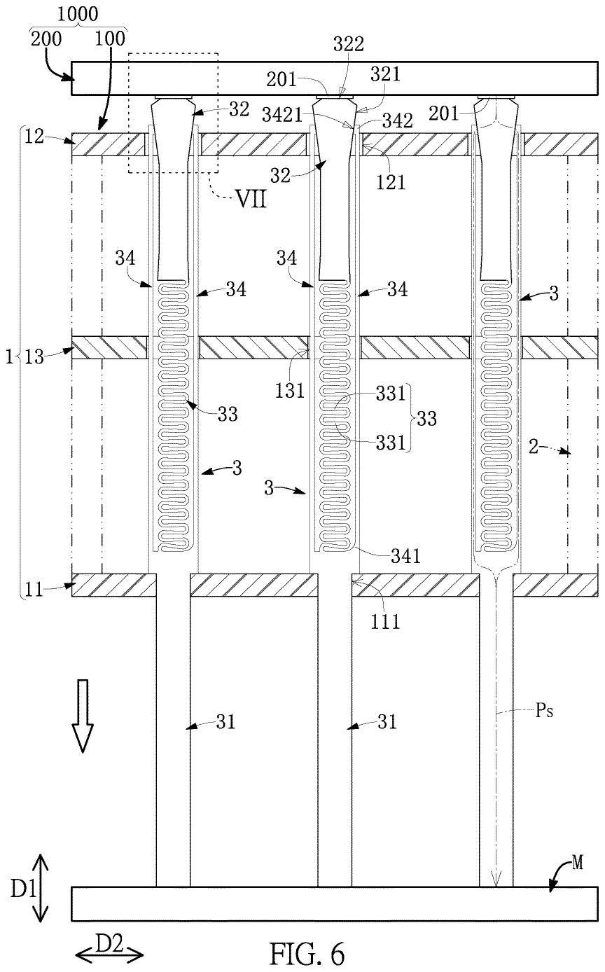

In summary, as shown in FIG. 6 to FIG. 9, when any one of the sheet-like probes 3 of the probe card 100 abuts against the DUT M through the testing segment 31 thereof and the spring segment 33 is pressed to be shortened by a length that is greater than the interval G, the free end portions 342 of the two clamping arms 34 move toward and abut against the two lateral contacting surfaces 321, respectively, and the two clamping arms 34 swing outwardly relative to the spring segment 33 and clamp the fixing segment 32 through the two free end portions 342 (e.g., the two mating surfaces 3421 respectively abutting against the two lateral contacting surfaces 321), so that the two clamping arms 34, the fixing segment 32, and the testing segment 31 are jointly configured to form a lateral signal transmission path Ps that is shorter than the initial signal transmission path P0, thereby effectively increasing signal transmission speed and signal transmission stability of the testing device 1000.

It should be noted that, in any one of the sheet-like probes 3 of the testing device 1000 provided by the present embodiment, the two clamping arms 34 are limited to be in contact with the fixing segment 32 that is fixed to the space transformer 200, and the two clamping arms 34 are swingable to clamp the fixing segment 32, thereby effectively increasing the signal transmission stability. In other words, any probe that contacts the test segment or that has a non-clamping contact manner cannot achieve the technical effect of the sheet-like probe 3 provided by the present embodiment and should not be compared thereto.

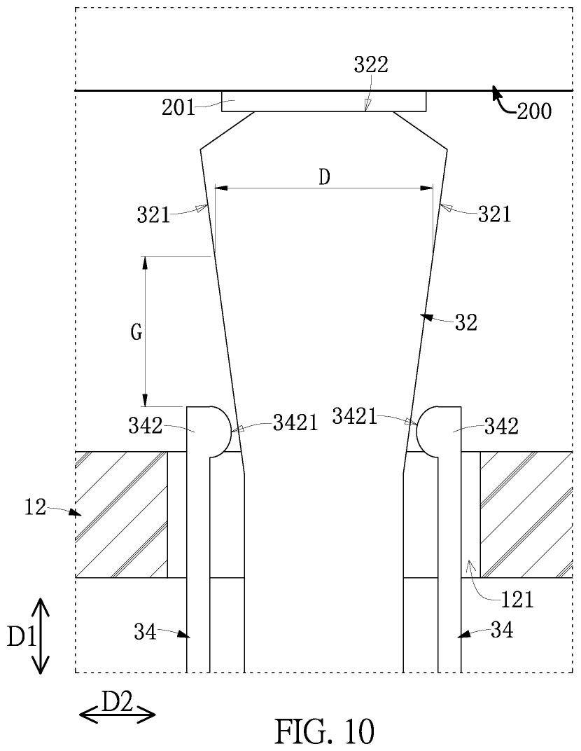

In addition, the mating surface 3421 of the free end portion 342 of any one of the two clamping arms 34 provided by the present embodiment is planar as shown in FIG. 1 to FIG. 9, but the present disclosure is not limited thereto. For example, as shown in FIG. 10, the mating surface 3421 of the free end portion 342 can be curved according to practical requirements.

### [Beneficial Effects of the Embodiment]

In conclusion, in any one of the testing device, the probe card, and the sheet-like probe provided by the present disclosure, the two clamping arms of the sheet-like probe are in cooperation with the fixing segment to form the lateral signal transmission path that is shorter than the initial signal transmission path, thereby effectively increasing the signal transmission speed of the testing device.

Moreover, in any one of the sheet-like probes of the testing device provided by the present disclosure, the two clamping arms are limited to be in contact with the fixing segment that is fixed to the space transformer, and the two clamping arms are swingable to clamp the fixing segment, thereby effectively increasing the signal transmission stability.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A testing device having a probe configuration, comprising:
a probe card including:
a first guiding board module;
a second guiding board module spaced apart from the first guiding board module along a first direction; and
a plurality of sheet-like probes inserted into the first guiding board module and the second guiding board module, wherein each of the plurality of sheet-like probes is integrally formed as a single one-piece structure and includes:
a testing segment at least partially protruding from the first guiding board module and configured to detachably abut against a device under test (DUT);
a fixing segment at least partially protruding from the second guiding board module, wherein the fixing segment has two lateral contacting surfaces and a bonding surface that is connected to the two lateral contacting surfaces, and an arrangement distance between the two lateral contacting surfaces gradually increases in a direction away from the testing segment;
a spring segment that connects the fixing segment and the testing segment, wherein the testing segment, the fixing segment, and the spring segment jointly define an initial signal transmission path; and
two clamping arms respectively arranged at two opposite sides of the spring segment, wherein each of the two clamping arms has a connection end portion connected to the testing segment and a free end portion that is spaced apart from the fixing segment, and wherein each of the two clamping arms does not protrude from the first guiding board module and protrudes from the second guiding board module through the free end portion;
wherein the two lateral contacting surfaces are respectively located in two extension paths defined by extending the free end portions of the two clamping arms along the first direction, and each of the two lateral contacting surfaces is spaced apart from a corresponding one of the free end portions along the first direction by an interval; and
a space transformer including a plurality of metal pads, wherein the bonding surfaces of the fixing segments of the plurality of sheet-like probes are respectively fixed to the plurality of metal pads of the space transformer;
wherein, when any one of the plurality of sheet-like probes of the probe card abuts against the DUT through the testing segment thereof and the spring segment is pressed to be shortened by a length that is greater than the interval, the free end portions of the two clamping arms move toward and abut against the two lateral contacting surfaces, respectively, and the two clamping arms swing outwardly relative to the spring segment and clamp the fixing segment through the two free end portions, so that the two clamping arms, the fixing segment, and the testing segment are jointly configured to form a lateral signal transmission path that is shorter than the initial signal transmission path.

2. The testing device according to claim 1, wherein the first guiding board module has a plurality of first thru-holes, the testing segments of the plurality of sheet-like probes respectively pass through the plurality of first thru-holes, and the connection end portions of the two clamping arms of each of the plurality of sheet-like probes abut against an inner surface of the first guiding board module.

3. The testing device according to claim 1, wherein the second guiding board module has a plurality of second thru-holes, the fixing segments of the plurality of sheet-like probes respectively pass through the plurality of second thru-holes, and at least one of the two clamping arms of each of the plurality of sheet-like probes is spaced apart from an inner wall of the corresponding second thru-hole so as to be swingable outwardly relative to the spring segment.

4. The testing device according to claim 1, wherein, in each of the plurality of sheet-like probes, the free end portion of any one of the two clamping arms has a mating surface that is parallel to the corresponding lateral contacting surface.

5. The testing device according to claim 1, wherein, in each of the plurality of sheet-like probes, the spring segment has a plurality of elastic portions that are sequentially connected to each other and that are of a same shape.

6. The testing device according to claim 1, wherein, in each of the plurality of sheet-like probes, the spring segment has a plurality of first elastic portions and a plurality of second elastic portions, and the plurality of first elastic portions and the plurality of second elastic portions are sequentially connected to each other and that are of different shapes.

7. The testing device according to claim 1, wherein, in each of the plurality of sheet-like probes, each of the two clamping arms is swingable outwardly relative to the spring segment by a maximum swing angle that is less than or equal to 3 degrees, and the initial signal transmission path is configured to not transmit signal.

8. The testing device according to claim 1, wherein the probe card includes a third guiding board module that is arranged between and spaced apart from the first guiding board module and the second guiding board module along the first direction, and the plurality of sheet-like probes are inserted into the third guiding board module.

9. A probe card, comprising:
a first guiding board module;
a second guiding board module spaced apart from the first guiding board module along a first direction; and
a plurality of sheet-like probes inserted into the first guiding board module and the second guiding board module, wherein each of the plurality of sheet-like probes is integrally formed as a single one-piece structure and includes:
a testing segment at least partially protruding from the first guiding board module and configured to detachably abut against a device under test (DUT);
a fixing segment at least partially protruding from the second guiding board module, wherein the fixing segment has two lateral contacting surfaces and a bonding surface that is connected to the two lateral contacting surfaces, and an arrangement distance between the two lateral contacting surfaces gradually increases in a direction away from the testing segment;
a spring segment that connects the fixing segment and the testing segment, wherein the testing segment, the fixing segment, and the spring segment jointly define an initial signal transmission path; and
two clamping arms respectively arranged at two opposite sides of the spring segment, wherein each of the two clamping arms has a connection end portion connected to the testing segment and a free end portion that is spaced apart from the fixing segment, and wherein each of the two clamping arms does not protrude from the first guiding board module and protrudes from the second guiding board module through the free end portion;
wherein the two lateral contacting surfaces are respectively located in two extension paths defined by extending the free end portions of the two clamping arms along the first direction, and each of the two lateral contacting surfaces is spaced apart from a corresponding one of the free end portions along the first direction by an interval;
wherein, when any one of the plurality of sheet-like probes of the probe card abuts against the DUT through the testing segment thereof and the spring segment is pressed to be shortened by a length that is greater than the interval, the free end portions of the two clamping arms move toward and abut against the two lateral contacting surfaces, respectively, and the two clamping arms swing outwardly relative to the spring segment and clamp the fixing segment through the two free end portions, so that the two clamping arms, the fixing segment, and the testing segment are jointly configured to form a lateral signal transmission path that is shorter than the initial signal transmission path.

10. A sheet-like probe having a longitudinal direction parallel to a first direction, the sheet-like probe comprising:
a testing segment configured to detachably abut against a device under test (DUT);
a fixing segment having two lateral contacting surfaces and a bonding surface that is connected to the two lateral contacting surfaces, wherein an arrangement distance between the two lateral contacting surfaces gradually increases in a direction away from the testing segment;
a spring segment that connects the fixing segment and the testing segment, wherein the testing segment, the fixing segment, and the spring segment jointly define an initial signal transmission path; and
two clamping arms respectively arranged at two opposite sides of the spring segment, wherein each of the two clamping arms has a connection end portion connected to the testing segment and a free end portion that is spaced apart from the fixing segment;
wherein the two lateral contacting surfaces are respectively located in two extension paths defined by extending the free end portions of the two clamping arms along the first direction, and each of the two lateral contacting surfaces is spaced apart from a corresponding one of the free end portions along the first direction by an interval;
wherein, when the sheet-like probe abuts against the DUT through the testing segment thereof and the spring segment is pressed to be shortened by a length that is greater than the interval, the free end portions of the two clamping arms move toward and abut against the two lateral contacting surfaces, respectively, and the two clamping arms swing outwardly relative to the spring segment and clamp the fixing segment through the two free end portions, so that the two clamping arms, the fixing segment, and the testing segment are jointly configured to form a lateral signal transmission path that is shorter than the initial signal transmission path.
